(19) United States
(12) Patent Application Publication
(10) Pub. No.: US 2013/0335079 A1
(43) Pub. Date: Dec. 19, 2013

(54) NUCLEAR MAGNETIC RESONANCE PROBE HEAD AND METHOD WITH MULTI-FUNCTIONAL SAMPLE ROTATION

(71) Applicant: Ago SAMOSON, Tallinn (EE)

(72) Inventor: Ago SAMOSON, Tallinn (EE)

(21) Appl. No.: 13/846,121

(22) Filed: Mar. 18, 2013

Related U.S. Application Data
(63) Continuation-in-part of application No. PCT/EP2011/066159, filed on Sep. 16, 2011.
(60) Provisional application No. 61/383,352, filed on Sep. 16, 2010.
(60) Provisional application No. 61/391,172, filed on Oct. 8, 2010.

(51) Int. Cl. G01R 33/28; G01R 33/50; G01R 33/483

(52) U.S. Cl. CPC G01R 33/28; G01R 33/483; G01R 33/50
USPC 324/309; 324/318

(57) ABSTRACT

Multi-functional sample rotation extends function of the MAS beyond suppression of the line-broadening. It is achieved with pivotal or axial displacement of the rotor. Specific embodiments are defined by methods for spin-distance or particle size measurements and efficient high-resolution DNP.

### FIELD OF THE INVENTION

This invention relates generally to the field of nuclear magnetic resonance (NMR) spectroscopy and, more particularly, to the sample spinning used in study of solid samples.

### BACKGROUND OF THE INVENTION

The Nuclear Magnetic Resonance spectroscopy is used to register a characteristic, chemical bonding and local magnetic field dependent response of nuclear spin precession rate in the strong polarizing magnetic field. NMR technology uses generally various measurement components: static magnetic fields and field gradients, low-, radiofrequency and microwave electromagnetic pulses, matter exchange, temperatures, mechanical sample rotation etc. NMR measurement act comprises a signal preparation period and actual data collection by digitization of the voltage which is induced according to Faraday's lay by the precession of magnetic nuclear spins. Radiofrequency pulses (“rf pulses”), oscillating at, or close to, the nuclear spin precession rates, change the spin magnetic moment direction and are deployed for sculpting spin precession to closest of the desired information. The observable spin EMF originates from an initial macroscopic polarization. This polarization is proportional to the difference of spin populations at energy levels, created by the interaction of the spin magnetic moment with the polarizing magnetic field. The polarization forms in a process of thermal relaxation, which can be a very important parameter of experiment (measurement act) and determine spectrometer throughput. The total speed and sensitivity of NMR analyses, comprising a number of added measurement acts, is usually proportional to the relaxation rate and population difference. If the thermal relaxation is locally faster in certain places, a process called “spin diffusion” will help to distribute the polarization homogeneously over the spin system of a studied sample. The thermal equilibrium magnetization level can be further increased, theoretically up to ca γₑ/γ_{I} times, by forming nuclear-electron spin subsystems. This process is called Dynamic Nuclear Polarization (DNP) and requires irradiation of electron spins at their respective magnetic resonance frequency, which is γₑ/γ¹_{H}˜660 times higher than hydrogen NMR frequency and technically in a microwave or Terahertz region. The sensitivity can also increased by a temperature factor, i.e. capitalizing on higher electron or nuclear spin polarizations at lower temperatures of their environment.

A common feature of many experiments is the sample spinning at a certain, called “magic”, angle. It equals to approximately 54.7 deg and derives from a root of the second rank Legendre polynomial. The origin of this particular angle reflects the fact of reducing or removing many orientation dependent spin-interactions, where the “orientation” is defined by direction of the local molecular structure in the magnetic field. As a result of Magic Angle Spinning (MAS), the composite, observable spectral line from multiply oriented particles or molecules becomes orientation independent and with that much narrower and more intense. The sample rotation is usually provided by a motion of a cylindrical, single compartment rotor, placed in gas lubricated low friction bearings. The bearings are held by the stator of matching length and at a fixed angle to the magnetic field. The angle can be externally tuned to accurate setting. This patent will describe novel ways how the rotor-stator design and sample rotation can be extended to axial motion, deviated angles, variable speeds and temperatures in order to enhance the sensitivity and information from the nuclear spin position or environment.

So far the prior art technical solutions of sample spinning have been used generally for having the rotation rate sufficiently fast and at a magic angle to achieve the desired resolution. Prior art describes also few extensions: Double Rotation, Stop-and-Go, Dynamic Angle Spinning and Speed Ramp, designed for respective, specific applications each.

Unlike prior art, where the sample spinning has considered as a monotonous motion about certain angle or angles (Double Rotation) or flipped while the spin evolution is interrupted for the flip moment (Dynamic Angle Spinning), and at a fixed axial position and/or temperature, we propose a more generalized method, offering also simultaneous combination of several features. The angle is flipped one or more times during the spin coherence time and also axial position, speed and temperature are altered during the measurement process with purpose of improving sensitivity and information quality (FIG. 1).

### SUMMARY OF THE INVENTION

We propose a set of new rotor motion properties and associated probe construction elements, providing axial and pivotal motion of the rotor and related measurement methods (FIG. 2).

To ensure the high speed of the rotation angle change and accuracy of the angle, we propose stoppers for stator positioning. Two independent stoppers 21-22 are needed for one sided deviation, four stoppers 23-26 and one lever 27 are required for three positions for tilting the stator about pivot point. The stoppers can be finely adjusted by special tuners, operated for example by piezo-electric elements. Piezo-electric elements can also directly drive the spinning angle change.

We also propose a new and fast mechanism for actuation of pivotal motion of the stator, using polarizing field 28 of the NMR magnet itself. A suitably wound current loop 29 is placed in the field of the polarizing magnet with the loop plane approximately along the field axis. A mechanical torque will act on the loop according Lorentz force law when passing current in one or another direction through the loop. This torque is carried over by a system of strings, belts, pulleys or pneumatic tubing 30 to the stator 19, making it swing about the pivot point 20. We also propose the hydraulic tubing as the novel way of connecting actuation and stator that determines the axis of rotation.

We propose also a system for compensating (shimming) magnetic field homogeneity distortion, possibly generated by the actuator loop. It may consist of the loop of similar geometry, moving in the opposite direction or other coils of suitable geometry and position 31.

We also propose axially multi-compartment stator-rotor arrangements 37-39 (see FIG. 4). By keeping the rotor in bearings 40-42 and homogeneous high field section of the magnet, axial repositioning of the rotor can be compatible with, and beneficial to, operation under conditions of experimental interest and reduce the overall signal collection time and/or improve information quality. We claim also that separation of the optical, microwave and/or radiofrequency operation modes and/or various temperatures or other experimental parameters (field gradients, matter exchange etc) to two or more separate compartments 38 and 39 between which part of or full sample is commuted, improves efficiency of the experiment, in particular if experimental conditions are otherwise conflicting. We propose extra radial bearings 40-43 and pneumatic actuator system for fast rotor shuttling. We also claim that axial shuttling of the rotor allows for more efficient use of the spectrometer time (see FIG. 5): spins in part of the sample 44 can relax to thermal equilibrium or be subjected to different experimental conditions as listed, but not only, above, while the other 45 is used for the data collection and/or subjected to different conditions. Unlike multiple stator solutions of prior art, this design does not compromise homogeneity or require extended correction of the magnetic field during the signal collection, since only the data acquisition region 45 requires usually the best homogeneity. Multi-compartment stator may feature microwave resonator which allows for reduction of the microwave power used for DNP. In that case various low-power microwave sources can be used. We propose to combine DNP NMR probe with local gyrotron. We propose weakly-relativistic operation principle of gyrotron for a minimal pertubation of the field homogeneity.

Novel technical features of sample spinning can be used in, and are critical for various novel methods: particle shape and size measurement, molecular structure determination, study of in situ electrochemical reactions and sensitivity-resolution optimized DNP.

### BRIEF DESCRIPTION OF THE DRAWINGS

FIG. 1. Variety of mechanical manipulations of rotor.

FIG. 2. Rotation angle adjustment.

FIG. 3. Timing diagram for multiple-selective distance measurements experiment.

FIG. 4. Axial relocation of the rotor during measurement process.

FIG. 5. Multiple compartment stator.

FIG. 6. Magnetic field profile in NMR magnet.

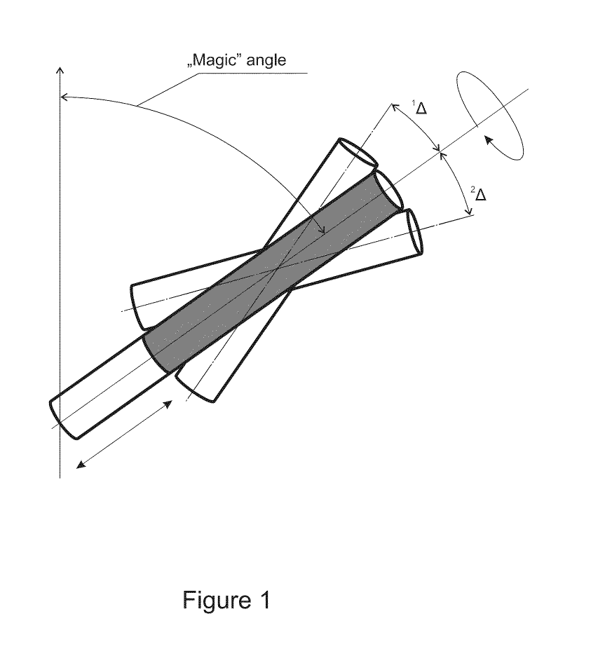

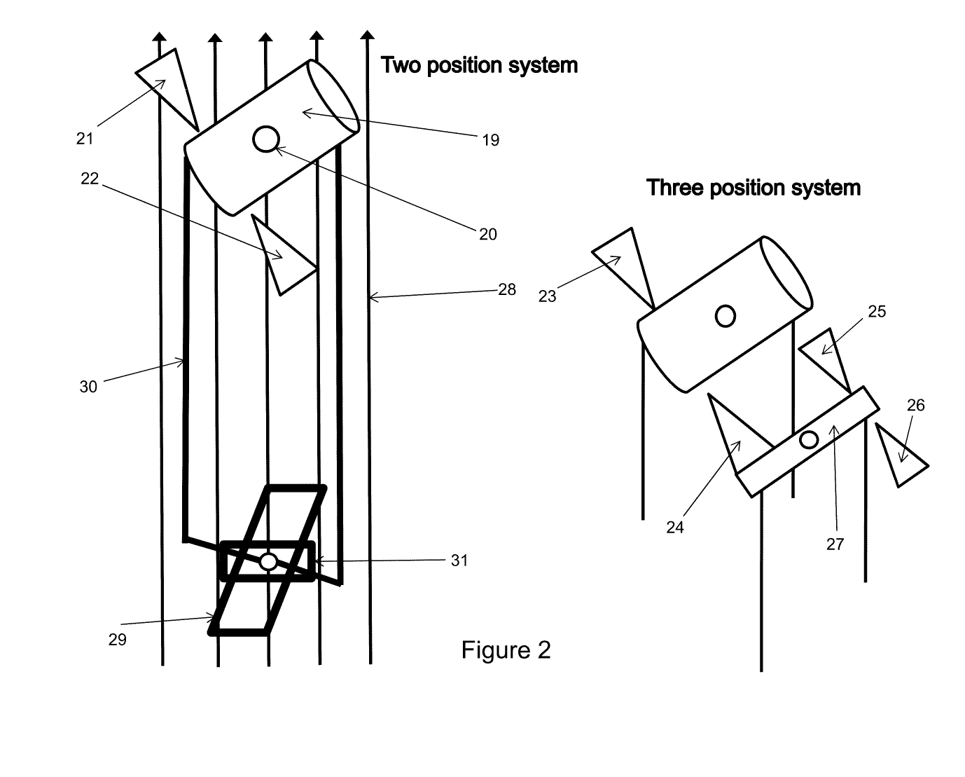

### DETAILED DESCRIPTION OF THE PREFERRED EMBODIMENTS AND METHODS

### 1. Control of Spin Diffusion for Sensitivity Enhancement and Particle Shape Measurements

The thermal equilibration (relaxation) of the nuclear spin is required for generation of a measurable macroscopic polarization, inducing voltage in the detector. Many factors may determine the relaxation rate, however, native or specially introduced paramagnetic centres may form a dominant mechanism³.

We claim that then the nuclear spin polarization dynamics can be comprehensively described and altered experimentally in order to deduce the structural data or increase the rate of data collection and with that sensitivity. Temporary deviation of the sample rotation angle from the “magic” value can be used to increase the spin-diffusion rate. In the case where structure or the sample contains dilute relaxation centres, i.e. locations where spin polarization and lattice energy are quickly equilibrated, or electron spin together with nuclear spins forms energetic subsystem of spins, formation of true or quasi-equilibrium with a larger spin system is influenced strongly by the spin-diffusion rate to those centres. The spin-diffusion rate depends on spin dipolar couplings and is faster for stronger couplings. We claim that if the sample is rotated at other than the “magic” angle, the dipolar coupling is less suppressed, consequently the spin-diffusion rate is faster and this effect can be used for improved spectrometer throughput. By a natural or artificial doping, some samples, for example proteins, can be supplemented by the paramagnetic relaxation centres. Faster spin relaxation allows for a faster repetition of the measurement acts, leading to overall saving in the data acquisition time and more efficient use of the spectrometer, alternatively, it also allows for a study of smaller sample quantities.

We also propose this effect as a method to measure size of large molecules or atomic/molecular complexes. Measurement of the relaxation in an integral or selective, location specific manner gives via spin-diffusion time information about the distance from the relaxation centres. We claim that by variation of the angle deviation and/or the spinning speed, which also changes the residual couplings between spins, the spin diffusion rate can be adjusted to a most convenient level and/or measurements can be made systematically as a function of spinning speed or deviation angle. With that disturbing background effects can be screened out in order to determine the desired values with a better accuracy.

### 2. Accurate Measurement of Multiple Spin Distances.

For the description of the method associated with the multiple, including at least one fast, changes of the rotation angle during spin coherence time, we shall describe development of the magnetization of a nuclear spin “I” during the measurement act by a phase φᵢ

$${ϕ}_{I} = [ {μ}_{0} \frac{{γ}_{S} {γ}_{I}}{{r}^{3}} ( 3 {cos}^{2} θ - 1 ) ( 3 {cos}^{2} ( {θ}_{M} + Δ ) - 1 ) {m}_{S} + {J}_{IS} {m}_{S} + {σ}_{I} ] T \qquad ( 1 )$$

where
ms is magnetic quantum number of an interacting spins S, assuming values ½ and −½ depending on orientation along the magnetic field axis,
γ_{S,I} are respective magnetogyric constants,
μ₀ magnetic permeability in vacuum,
r distance between nuclei,
θ statistical angle between the line connecting spins I and S and the magnetic field direction,
θ_{M}+Δ angle of rotation with an explicit deviation part Δ,
σ_{I} is a sum of isotropic and anisotropic components of chemical shift of nuclear site I and T duration of the measurement act or a part of it,
J_{IS} term represents indirect, chemical bond mediated dipolar interaction between the spins.
   The expression (1) assumes that non-diagonal matrix elements of the interaction Hamiltonian are negligible compared to diagonal, determined mostly by a difference in the chemical shifts. This approximation improves with increasing magnetic fields and smaller deviation from the “magic” angle, explained below. The whole expression can be written in shorthand as

φ_{I}(d_{IS}+j_{IS}+ω_{I})T (2)

The sample rotation is generally used to average orientation dependent environment or structure effects (caused usually by anisotropy of crystalline lattice or dipolar interactions with other spins) of the nuclear spin precession, as a result the spectral line from a given nuclear site becomes narrower and gains in the amplitude. The special angle of the rotation axis, assuming Δ=0, derives mathematically from a root of the second order Legendre polynomial

P₂(cos θ_{M})=0

as

θ_{M}=arccos(1/√3) (3)

and corresponds to the angle between diagonal and edge in the cube and is noted as “magic” in the following, since direct dipolar interaction term dis turns zero in that case. By adding a certain non-zero, positive or negative value of Δ to the “magic” angle, dipolar interaction starts to modify the signal phase again with a scaling value depending on the size of Δ.

The rf pulses will, via virtue of changing the quantum numbers m_{I,S,J}, alter the sign of direct dipolar interaction term in expression (2), and change the sign of the whole accumulated phase, if acting on observable spin I. The measurement process consists of measurement acts (also called scans), which are recycled to add up better signal to noise ratio, and optionally repeated systematically with some parameter change for study of specific dependencies or additional Fourier analyses.

As can be seen from formula (1) above, the nuclear spin precession rate depends on the magnetic field, generated by other nuclear magnetic moments in the vicinity. Presence of the other spin is mathematically described by a product formula of the magnetic dipolar interaction, which involves factors of relative spin orientation (m_{S}) and inverse third power of the distance between spins r. Distances r can be used for determination of structural properties of a studied material. In the solid phase many spins interact and thus information depends on many distances and angles, which complicates accurate recording of the characteristic chemical shifts or other desired information. A term “dipolar truncation” has been introduced to reflect the principal difficulties¹. A signal phase for the three spins, forming a system connected by dipolar interactions, can for present purposes be expressed for spins S, I and J as

φ_{S}=(d_{IS}+d_{SJ}+j_{IS}+j_{SJ}+ω_{S})T

φ_{I}=(d_{IS}+d_{IJ}+j_{IS}+j_{IJ}+ω_{I})T

φ_{J}=(d_{IJ}+d_{SJ}+j_{IJ}+j_{SJ}+ω_{J})T (4)

In order to overcome any unwanted line-broadening, a fast mechanical rotation of the sample about the “magic” angle to the polarizing magnetic field is used. The effect of this rotation is that in the formula for dipolar interaction (as (1) above), average angular part over the rotation period for all spin-pairs becomes equal to zero, reducing thus the line-broadening in the first approximation. However, in this case nuclear spins also do not sense presence of the other spins and valuable structural information remains hidden. Numerous methods of the spin manipulation have been developed to recover the spin-spin distances, based mostly on repeated selective flip(s) of spins with respect to the magnetic field. However, these methods are reported to fail, if multiple spin distances have to be measured, or if one distance is significantly shorter than other of interest (“dipolar truncation”).

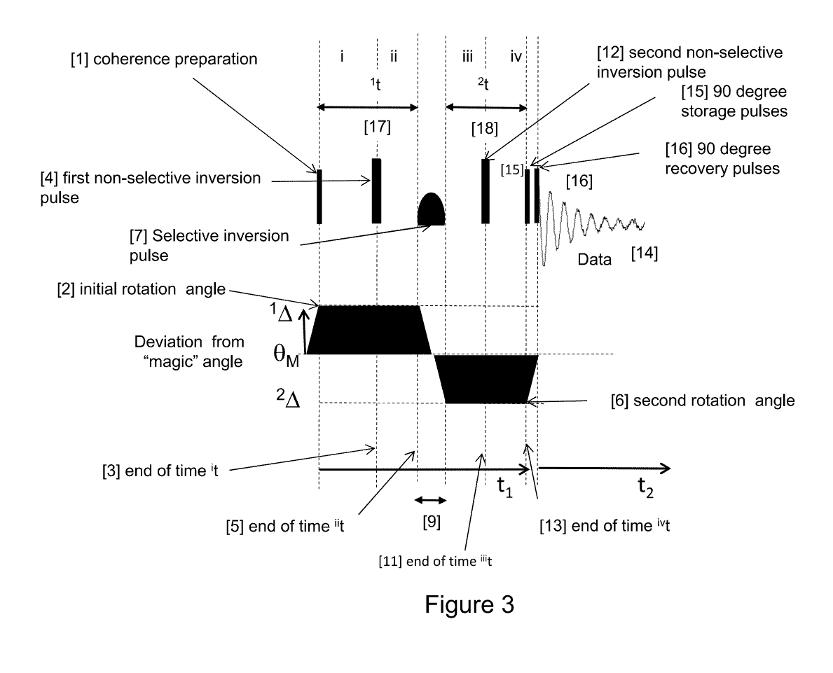

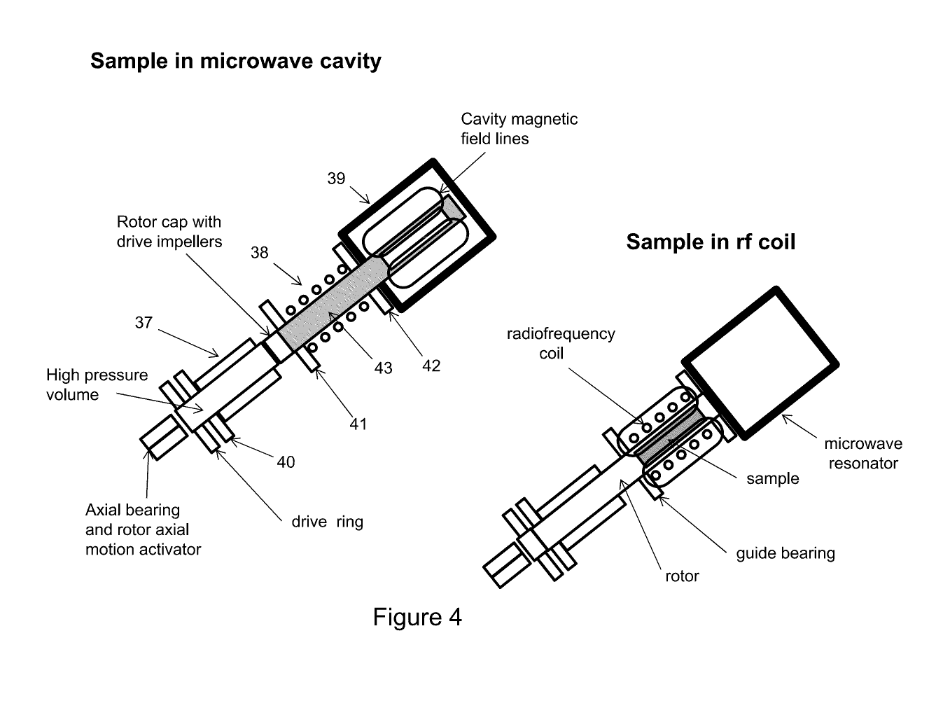

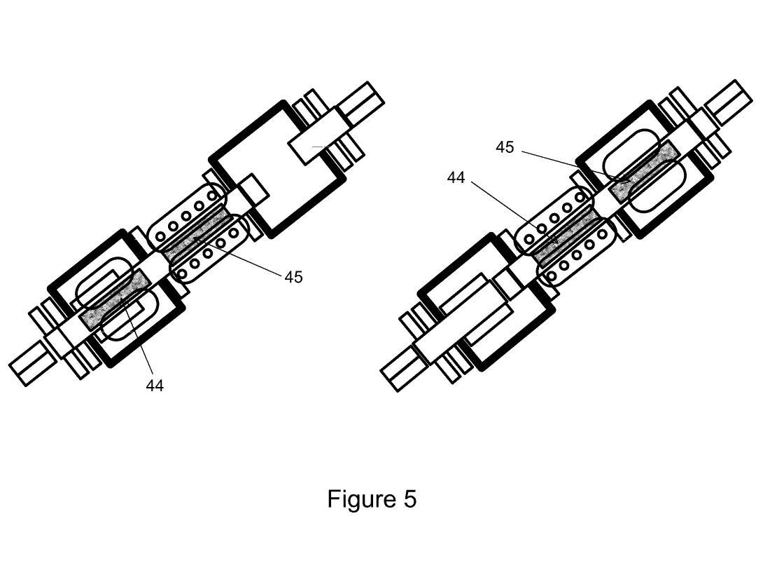

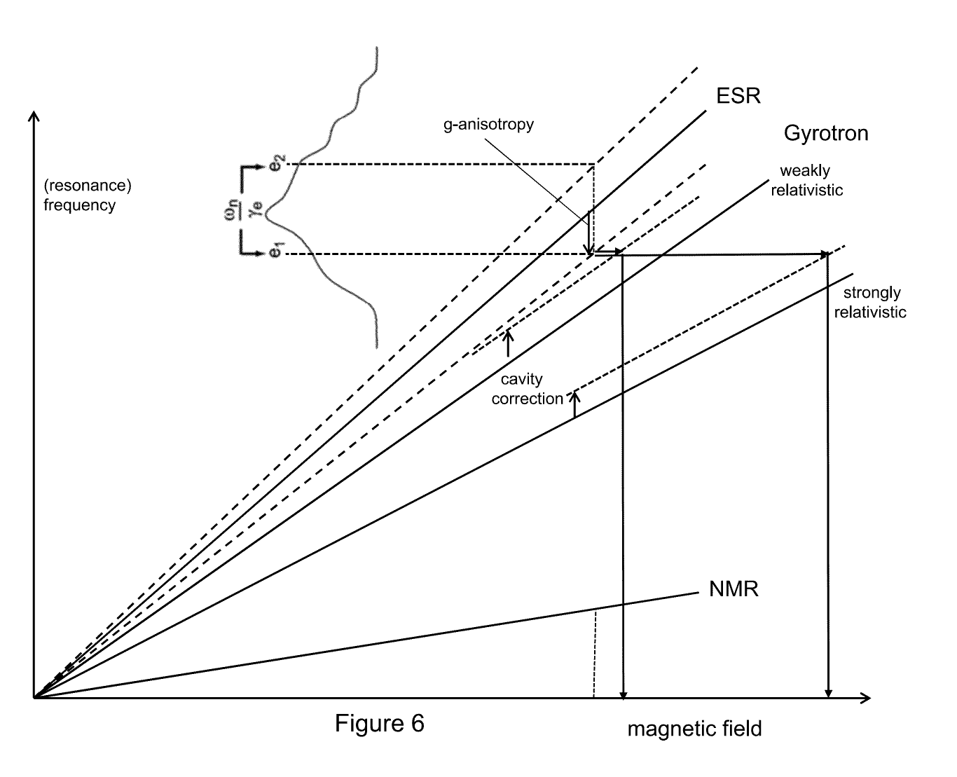

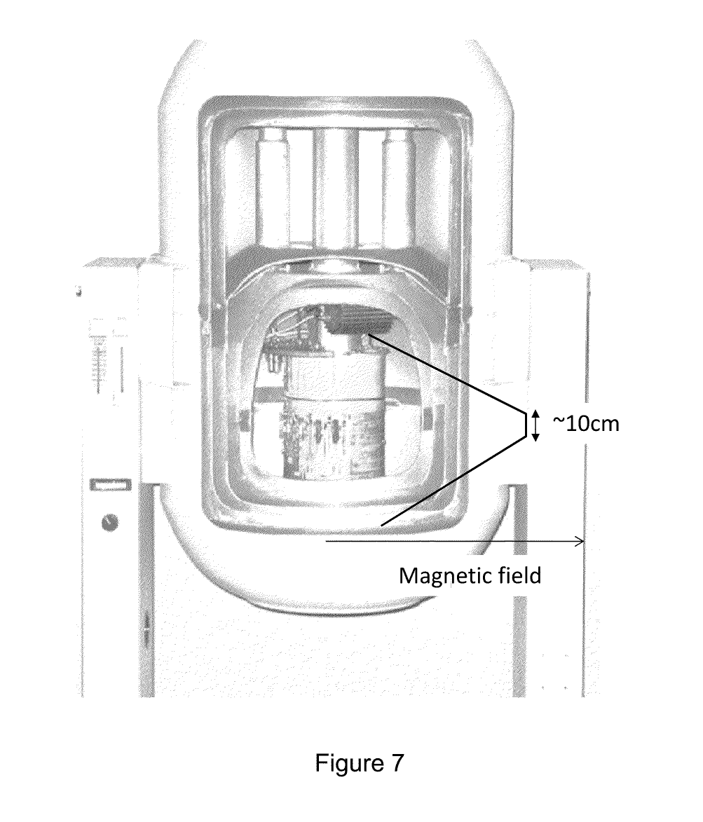

Prior art reports the method to measure selectively the distance of one spin to the other in the presence of third or more spins² with deviation of the rotation from the “magic” value. We propose a new, extended method, where by declination of the rotation angle from the “magic” value distances to more than one spin are measured simultaneously. Unlike in experiments of prior art, we use multiple deviations from the “magic” value with the purpose of compensation of the deviation effect, enabling a “filtering” of nuclear spin interactions. The signal recording can be performed either at the “magic” angle or the deviated value, if it does not critically affect the resolution, in one measurement act (FIG. 3). The experiment works as follows:

The spin coherence is prepared by some usual procedure, direct pulse excitation or cross polarization [1]. The rotation angle is prepared with offset ⁱΔ[2]. The following analyses assumes two categories of spins, one marked as “S” that is selectively inverted in the measurement act, and other, limited in this case to two and labeled as “I” and “J”, subject to non-selective preparation and the final source of the structural information. The phase of the spins “I” (same applies to “J”, formally indexes can be exchanged) by the end of time ⁱt [3] is

ⁱφ_{I}=(ⁱd_{IS}+ⁱd_{IJ}+j_{IS}+j_{IJ}+ⁱω_{I})ⁱt

After a non-selective inversion pulse [4] all phases acquire the opposite sign −ⁱφ_{I}. A consequent evolution during time ⁱⁱt generates additional phase

ⁱⁱφ_{I}=−(ⁱd_{IS}+ⁱd_{IJ}+j_{IS}+j_{IJ})ⁱⁱt+ⁱωᵢⁱⁱt

with a difference to the period “i” in the sign of the dipolar contributions. A total phase by the end of period “ii” [5] is −ⁱφ_{I}+ⁱⁱφ_{I}.

Now follows a simultaneous change of rotation angle to a new deviation value ⁱⁱⁱΔ[6] and selective pulse on spins “S” [7], which changes sign of respective terms. Following phase increment to end of third time period [11] is

ⁱⁱⁱφ_{I}=−(−ⁱⁱⁱd_{IS}+ⁱⁱⁱd_{IJ}−j_{IS}+j_{IJ})ⁱⁱⁱt+ⁱⁱⁱω_{I}ⁱⁱⁱt

Now again a non-selective inversion pulse [12] is applied, resulting in another inversion of a total phase to

−(−ⁱφ_{I}+ⁱⁱφ_{I}+ⁱⁱⁱφ).

The fourth period of measurement act [13] adds phase with effect of all dipolar terms inverted

^{iv}φ_{I}=(−ⁱⁱⁱd_{IS}+ⁱⁱⁱd_{IJ}−j_{IS}+j_{IJ})^{iv}t+ⁱⁱⁱω_{I}^{iv}t

The signal [14] can be read out while the rotation is at “magic” angle again, or, if the resolution is not prohibitively compromised, at the last setting of the angle. In this case, the need for additional storage-recovery pulses [15], [16] and associated loss of the signal by factor √2 is avoided. As a final result, the total phase can be described as

$${ϕ}_{I} \begin{matrix}= - ( - {}_{}^{i}{ϕ}{}_{I}^{} + {}_{}^{ii}{ϕ}{}_{I}^{} + {}_{}^{iii}{ϕ}{}_{I}^{} ) + {}_{}^{iv}{ϕ}{}_{I}^{} \\ = {}_{}^{i}{ϕ}{}_{I}^{} - {}_{}^{ii}{ϕ}{}_{I}^{} - {}_{}^{iii}{ϕ}{}_{I}^{} + {}_{}^{iv}{ϕ}{}_{I}^{} \\ = ( {}_{}^{i}{d}{}_{IS}^{} + {}_{}^{i}{d}{}_{IJ}^{} + {j}_{IS} + {j}_{IJ} + {}_{}^{i}{ω}{}_{I}^{} ) {}^{i} t + \\ ( {}_{}^{i}{d}{}_{IS}^{} + {}_{}^{i}{d}{}_{IJ}^{} + {j}_{IS} + {j}_{IJ} ) {}^{ii} t - {}_{}^{i}{ω}{}_{I}^{} {}^{ii} t ++ \\ ( - {}_{}^{iii}{d}{}_{IS}^{} + {}_{}^{iii}{d}{}_{IJ}^{} - {j}_{IS} + {j}_{IJ} ) {}^{iii} t - {}_{}^{iii}{ω}{}_{I}^{} {}^{iii} t + \\ ( - {}_{}^{iii}{d}{}_{IS}^{} + {}_{}^{iii}{d}{}_{IJ}^{} - {j}_{IS} + {j}_{IJ} ) {}^{iv} t + {}_{}^{iii}{ω}{}_{I}^{} {}^{iv} t \\ = {}_{}^{i}{d}{}_{IS}^{} ( {}^{i} t + {}^{ii} t ) - {}_{}^{iii}{d}{}_{IS}^{} ( {}^{iii} t + {}^{iv} t ) + \\ {}_{}^{i}{d}{}_{IJ}^{} ( {}^{i} t + {}^{ii} t ) + {}_{}^{iii}{d}{}_{IJ}^{} ( {}^{iii} t + {}^{iv} t ) + \\ {j}_{IS} ( {}^{i} t + {}^{ii} t ) - {j}_{IS} ( {}^{iii} t + {}^{iv} t ) + \\ {j}_{IJ} ( {}^{i} t + {}^{ii} t ) + {j}_{IJ} ( {}^{iii} t + {}^{iv} t ) + \\ {}_{}^{i}{ω}{}_{I}^{} ( {}^{i} t - {}^{ii} t ) + {}_{}^{iii}{ω}{}_{I}^{} ( - {}^{iii} t + {}^{iv} t )\end{matrix}$$

If two time periods are pairwise equal, and incremented in a systematic manner for further analyses, ⁱt=ⁱⁱt=n ⁱτ/4 and ⁱⁱⁱt=^{iv}t=n ⁱⁱⁱτ/4, the last term falls off, and signal phase depends only on dipolar interactions

$${}_{}^{( n )}{ϕ}{}_{I}^{} = ( {}_{}^{i}{d}{}_{IS}^{} {}^{i} τ - {}_{}^{iii}{d}{}_{IS}^{} {}^{iii} τ + {}_{}^{i}{d}{}_{IJ}^{} {}^{i} τ + {}_{}^{iii}{d}{}_{IJ}^{} {}^{iii} τ + {j}_{IS} ( {}^{i} τ - {}^{iii} τ ) + {j}_{IJ} ( {}^{i} τ + {}^{iii} τ ) ) n / 2$$

If j_{IJ} is small or can be neglected, then the signal of spin “I” depends only on interaction with a spin “S”, if

ⁱd_{IJ}ⁱτ=−ⁱⁱⁱd_{IJ}ⁱⁱⁱτ.

This condition can be fulfilled e.g. if

ⁱτ=ⁱⁱⁱτ=τ and

ⁱd_{IJ}=−ⁱⁱⁱd_{IJ}=d(θ_{M}+Δᵢ), ⁱⁱⁱd_{IJ}=d(θ_{M}+Δᵢᵢᵢ),

The last condition means about equal angle of deviation to both sides from “magic”

Δᵢ=˜−Δᵢᵢᵢ

if the angle Δᵢ remains small, depending on strength of interaction and desired accuracy, but generally less than ten degrees. In this case also the effect of indirect interaction “j_{IS}” vanishes and the precession phase of the observable spin “I” (and for similar reasons any other spin “J”, depends on direct dipolar interaction with the selectively inverted spin “S” and mutually on indirect spin interactions (apart “S”):

⁽ⁿ⁾φ_{I}=ⁱd_{IS}τn+j_{IJ}τn

These interactions can be revealed by a usual technique of 2D spectroscopy, where time-parameter varies systematically with n=1,2,3 . . . or in a more complicated manner for reduced total acquisition time and selective spectral region

t₁=τn

The systematic variation is not the only means of deduction of distance information from revealed d_{IS}, it can be by a suitable choice of points. In particular, time τ can be also set constant and angles varied such that the informative array (n) of phase values

⁽ⁿ⁾φ_{I}=⁽ⁿ⁾d_{IS}τ+j_{IJ}τ

forms as a result of different deviation angles ⁽ⁿ⁾Δᵢ and ⁽ⁿ⁾Δᵢᵢᵢ. This option allows to filter out also influence of indirect dipolar couplings j_{IJ}, since they only form a constant added to the deviation angle dependent signal.

Other, undefined relaxation or dispersion factors may compound to the signal. This effect can be determined and subtracted from a composite signal by repeating the experiment without the selective inversion pulse [7] on spin “S”.

The idea of patented experiment can be described also without formalism as follows.

By a suitable ratio of time periods [17] and [18], spent at either side (in case of small deviations the ratio is approximately equal to one) signal of all spins returns principally to the value of no deviation, i.e. echo is formed. However, the echo is reduced for those pairwise interactions, where one of the spins (S) has been inverted by the selective rf pulse [7]. The amount of reduction depends on the deviation angle, time of the deviation and inverse cube of the internuclear distance. Since the first two parameters can be experimentally controlled, this method enables to determine distances between the pair of nuclei. If the nucleus with inverted spin magnetization interacts with more nuclei (I, J, . . . ), then by measuring respective echo modulations on other spins I, J, . . . , distances of those nuclei to the inverted spin can be determined, like S-I, S-J, . . . . The inverted spin can be of the same type nucleus (homonuclear system), if the spectral distance allows selective inversion, or different (heteronuclear system). Here we note that generally not the perfect spin inversion is required to generate the echo modulation, but it is recommendable for a maximum effect. To further increase the accuracy of distance measurements and to estimate the influence of possible relaxation and other disturbing effects on the echo amplitude, experiments can be repeated with the spin inversion and non-inversion and subtracted from each other. For a better reduction of other possible artifacts, order of the angle deviation can also be changed. Experiments can also be repeated over various times of the angle deviation periods ¹t and ²t or various angles of the deviation [2] and [6] from the perfect “magic” value, the latter method has advantage of separating scalar and dipolar coupling effects on the spin precession. We claim also that the set of pairwise internuclear distances from one spin S (S-I, S-J, S-K, . . . ,) can be used for structural refinement of unknown systems at atomic and molecular level. We also claim that the experiment can be repeated with selecting other spins for selective inversion experiment to provide more data for structural restraints (J-I, J-S, J-K, . . . ,) or selection can be scanned over a spectral range, covering part of or entire spectrum, for the same purpose.

If spectral lines of the echo modulated spins overlap, they can be decomposed according to distance to the inverted spin. We claim that this method constitutes then an extension of the experiment to additional spectral dimension, also providing direct information on the internuclear distances.

### 3. Dynamic Nuclear Polarization (DNP)

Irradiation of the unpaired electron spin centres at a resonant microwave frequency can generate over the thermal-level nuclear spin polarization in a sub-system of the nuclear and electron spins, if they are sufficiently isolated from other relaxation mechanisms. This phenomenon is called Dynamic Nuclear Polarization. We propose a novel method, encompassing a compartmentalized stator with axial motion of the rotor. This apparatus and method can reduce the cost and improve efficiency of DNP because it is possible to optimize separately nuclear spin polarization process and signal detection conditions. First is generally conducted at a very low temperature to improve the polarization build-up by reducing the leak of energy from the electron-nuclear spin system to surroundings. The preferred temperature during nuclear spin signal detection is that of a functional state of biological systems, i.e. above melting or at body temperature, which usually provides also a much better resolution. Literature reports also imply the best electron-nuclear spin polarization transfer at relatively low sample rotation speeds, which again may be not optimal for actual signal measurement conditions. Described above axial motion mechanism is applicable and necessary in the context of optimal DNP. The compartmentalized design allows for the use of efficient, high quality and compact resonator structures during the nuclear spin polarization build-up. Both, high quality factor and compact volume of the resonator lead to a reduced power demand for the microwave source. We claim, that gyrotron devices as preferred high frequency microwave power sources can be operated in a practically same magnetic field as the field at the sample measurement position, obliviating technically complicated field increase, design special magnets or use of a separate magnet altogether. If only a watt or less of the microwave power is needed, gyrotron can be operated in a very weakly relativistic regime, meaning that increase of the electron mass and with that decrease in gyration frequency are small. Considering also an opposite frequency effect, a slight increase of the gyrotron frequency by the geometrical cavity factor, designed to promote emission over absorption during the gyrating motion of the electron through the cavity, the resulting output frequency may stay within band of the electron spin resonance line. With a right choice of a compound for the paramagnetic centers, for example biradical 1-(TEMPO-4-oxy)-3-(TEMPO-4-amino)propan-2-ol (TEMPO: 2,2,6,6-tetramethylpiperidin-1-oxyl), the spectral low end, shifted by the g-factor anisotropy contribution in the electron spin resonance line, can be expected to meet the gyrotron frequency.

### REFERENCES

1. Title: Dipolar truncation in magic-angle spinning NMR recoupling experiments Author(s): Bayro Marvin J.; Huber Matthias; Ramachandran Ramesh; et al. Source: JOURNAL OF CHEMICAL PHYSICS Volume: 130 Issue: 11 Article Number: 114506 DOI: 10.1063/1.3089370 Published: Mar. 21, 2009
2. Title: Longer-range distances by spinning-angle-encoding solid-state NMR spectroscopy, Author(s): Becker-Baldus Johanna; Kemp Thomas F.; Past Jaan; et al. Source: PHYSICAL CHEMISTRY CHEMICAL PHYSICS Volume: 13 Issue: 10 Pages: 4514-4518 DOI: 10.1039/c0cp02364g Published: 2011
3. Title: Nanomole-scale protein solid-state NMR by breaking intrinsic (1)H T(1) boundaries, Author(s): Wickramasinghe Nalinda P.; Parthasarathy Sudhakar; Jones Christopher R.; et al. Source: NATURE METHODS Volume: 6 Issue: 3 Pages: 215-218 DOI: 10.1038/NMETH.1300 Published: March 2009
U.S. Pat. No. 4,968,939, Pines, et al. Nov. 6, 1990, Method and apparatus for measuring the NMR spectrum of an orientationally disordered sample
4. U.S. Pat. No. 4,968,938, Pines, et al., Nov. 6, 1990, Method and sample spinning apparatus for measuring the NMR spectrum of an orientationally disordered sample
5. TOTAPOL: A Biradical Polarizing Agent for Dynamic Nuclear Polarization Experiments in Aqueous Media, Changsik Song, †Kan-Nian Hu, †‡Chan-Gyu Joo, ‡Timothy M. Swager, † and Robert G. Griffin, *‡, J. Am. Chem. Soc., 2006, 128 (35), pp 11385-11390
6. United States Patent Application 20120176133A1, Sirigiri, Jagadishwar R.; et al., Jul. 12, 2012, Integrated high-frequency generator system utilizing the magnetic field of the target application

What is claimed is:

1. A probe head used for sample spinning in study of solid samples in the nuclear magnetic resonance spectroscopy and for the spinning angle switching comprising a cylindrical, single compartment rotor providing motion for the sample rotation and placed in gas lubricated low friction bearings, whereas the bearings are held by the stator of matching length and at a fixed angle to the magnetic field, whereas the angle can be externally tuned to accurate setting, the device comprising at least two or more independent stoppers for positioning the stator of said device.

2. The probe head according to claim 1 where one or more stoppers are adjusted by special tuners, set mechanically or by piezo-electric elements.

3. The probe head according to claim 1 comprising a means for actuation of motion of the spinner housing, using the field of the NMR magnet itself, comprising a suitably wound current loop placed in the field of polarizing magnet with the loop plane approximately along the field axis whereas passing current in one or other direction through the loop a mechanical torque will act on the loop by Lorentz force law whereas said torque may be carried over by a system of strings, belt, pulleys, hydraulic or pneumatic tubing to the sample spinner, making it swing about the pivot point.

4. The probe head according to claim 1 comprising a system for compensating (shimming) magnetic field homogeneity distortion, possibly generated by the actuator loop comprising a loop of similar geometry, moving in opposite direction or other coils of suitable geometry and position.

5. A nuclear magnetic resonance probe head with multi-compartment stator structure, placed in or sufficiently near the homogeneous field volume in the magnet, and arranged such that the rotor with sample can be shuffled fast and repeatedly between compartments during signal accumulation.

6. The nuclear magnetic resonance probe head according to claim 5 comprising a stator with axial sections which can be independently optimized for specific purposes, possibly and not only including different rotation speeds, temperatures, photochemical activation and resonances at different frequencies.

7. The nuclear magnetic resonance probe head according to claim 5 comprising further one or more radial bearings or other low-friction supports that provide for easy and fast relocation of the rotor along spinning axis.

8. The nuclear magnetic resonance probe head according to claim 5 comprising interchangeable multiple axial sections of rotor filled with the sample to interleave periods of data acquisition and polarization preparation.

9. The nuclear magnetic resonance probe head according to claim 5 where one or multiple fiber lasers are used to heat up the sample by radial irradiation of the rotor.

10. A nuclear magnetic resonance method, where spin precession rate and/or amplitude is modified via dipolar interaction with the neighbouring spins by means of setting sample spinning axis to more than one value from the “magic” position for the controlled period of time with the values calculated for separation and measurement of direct dipolar interactions between the spins.

11. The nuclear magnetic resonance method according to claim 10 where nuclear spin coherence evolves while deviations ¹Δ and ²Δ from magic angle (measured as positive or negative values) and durations it and ²t are chosen such that condition
¹t*(Cos²(θ_{M}+¹Δ)−1)+²t*(Cos²(θ_{M}+²Δ)−1)=0 holds.

12. The nuclear magnetic resonance method according to claim 11 by using said declination from “magic” value to both sides from said magic value in one measurement where said experiment can be repeated with selecting other spins for selective inversion experiment (J-I, J-S, J-K, . . . , I-S, I-K, . . . ) to provide more data for structural restraints or selection is scanned over the spectral range for the same purpose.

13. A nuclear magnetic resonance method to measure size of large molecules (>10 kDa), atomic/molecular assemblies or other distances of interest by declination from “magic” value so that the spin diffusion will be adjusted to a convenient speed and/or measurements will be made systematically over a range of speeds or angles in order to determine the desired data, like distance over which the spin polarization has to propagate, with a better accuracy or the measurement process can be repeated at an increased rotation speed rate.

14. The nuclear magnetic resonance method according to claim 13 to measure size of large molecules (>10 kDa), atomic/molecular assemblies or other distances or parameters of interest by variation of the sample rotation speed.

15. Use of the gyrotron designed and located to operate in practically the same magnetic field region as NMR measurement.
